(19) United States
(12) Patent Application Publication
(10) Pub. No.: US 2025/0006534 A1
(43) Pub. Date: Jan. 2, 2025

(54) SEMICONDUCTOR TRANSFER DEVICE

(71) Applicant: Samsung Electronics Co., Ltd., Suwon-si (KR)

(72) Inventors: Seong Won Yeom, Suwon-si (KR); Ki Beom Kil, Suwon-si (KR); Byeong Kuk Park, Suwon-si (KR)

(21) Appl. No.: 18/426,702

(22) Filed: Jan. 30, 2024

(30) Foreign Application Priority Data
Jun. 27, 2023 (KR) 10-2023-0082693

(51) Int. Cl. H01L 21/677

(52) U.S. Cl. CPC H01L 21/67766

(57) ABSTRACT

A semiconductor transfer device includes a vertical extension part extending in a first direction and including a first surface and a second surface opposite to each other in a second direction crossing the first direction, a support part on the first surface of the vertical extension part and extending in the first direction, a horizontal plate on the support part and extending in the second direction, and including a corner at which a first edge extending in the second direction along a circumference of the horizontal plate and a second edge extending in a third direction crossing the first direction and the second direction along the circumference of the horizontal plate intersect, and a first-type guide part extending from an upper surface of the horizontal plate at the corner.

### CROSS-REFERENCE TO RELATED APPLICATION

This application claims priority under 35 U.S.C. 119 from Korean Patent Application No. 10-2023-0082693, filed on Jun. 27, 2023 in the Korean Intellectual Property Office, the contents of which are herein incorporated by reference in their entirety.

### BACKGROUND

The present disclosure relates to a semiconductor transfer device.

Semiconductor transfer containers may transfer wafers. The wafers may have various sizes depending on their use purposes. Accordingly, semiconductor transfer containers may also have various sizes.

Semiconductor transfer devices may accommodate semiconductor transfer containers having different sizes. The semiconductor transfer device may take out wafers from the semiconductor transfer containers accommodated in the semiconductor transfer device and sort or merge the wafers. However, one semiconductor transfer device may accommodate only one semiconductor transfer container, which is inefficient. Accordingly, it is desirable to develop a semiconductor transfer device for increasing efficiency of a semiconductor transfer process.

### SUMMARY

Aspects of the present disclosure provide a semiconductor transfer device capable of improving efficiency by accommodating various semiconductor transfer containers.

However, aspects of the present disclosure are not restricted to those set forth herein. The above and other aspects of the present disclosure will become more apparent to one of ordinary skill in the art to which the present disclosure pertains by referencing the detailed description of the present disclosure below.

According to an aspect of the present disclosure, there is provided a semiconductor transfer device including a vertical extension part extending in a first direction and including a first surface and a second surface opposite to each other in a second direction crossing the first direction, a support part on the first surface of the vertical extension part and extending in the first direction, a horizontal plate on the support part and extending in the second direction, and including a corner at which a first edge extending in the second direction along a circumference of the horizontal plate and a second edge extending in a third direction crossing the first direction and the second direction along the circumference of the horizontal plate intersect, and a first-type guide part extending from an upper surface of the horizontal plate at the corner.

According to another aspect of the present disclosure, there is provided a semiconductor transfer device including a vertical extension part extending in a first direction and including a first surface and a second surface opposite to each other in a second direction crossing the first direction, a support part on the first surface of the vertical extension part and extending in the first direction, a horizontal extension part on the support part and extending in the second direction, and including a third surface and a fourth surface opposite to each other in a third direction crossing the first direction and the second direction, a first guide cylinder on the third surface of the horizontal extension part and configured to transmit power, and a first-type guide part connected to the first guide cylinder and movable in the first direction, wherein the first-type guide part includes a vertical surface parallel to the third surface and an inclined surface forming an acute angle with an upper surface of the horizontal extension part.

According to still another aspect of the present disclosure, there is provided semiconductor transfer device including a vertical extension part extending in a first direction and including a first surface and a second surface opposite to each other in a second direction crossing the first direction, a support part on the first surface of the vertical extension part and extending in the first direction, a horizontal extension part on the support part and extending in the second direction, and including a third surface and a fourth surface opposite to each other in a third direction crossing the first direction and the second direction, a first guide cylinder on the third surface of the horizontal extension part and configured to transmit power, and a first-type guide part connected to the first guide cylinder and movable in the first direction, wherein the first-type guide part includes a vertical surface parallel to the third surface and a concave surface between the vertical surface and the third surface.

### BRIEF DESCRIPTION OF THE DRAWINGS

The above and other aspects and features of the present disclosure will become more apparent by describing in detail embodiments thereof with reference to the attached drawings, in which:

FIG. 1 is a view for describing a semiconductor transfer device according to some embodiments of the present disclosure;

FIG. 2 is an illustrative cross-sectional view taken along line A-A of FIG. 1;

FIG. 3 is an illustrative enlarged view of a rear surface of portion R1 of FIG. 1;

FIG. 4 is an illustrative view for describing a semiconductor transfer container;

FIG. 5 is an illustrative view for describing the semiconductor transfer container accommodated in the semiconductor transfer device according to some embodiments of the present disclosure;

FIGS. 6 to 8 are views for describing a guide part of the semiconductor transfer device according to some embodiments of the present disclosure;

FIGS. 9 to 12 are cross-sectional views for describing an operating method of the semiconductor transfer device according to some embodiments of the present disclosure;

FIG. 13 is a view for describing a semiconductor transfer device according to some embodiments of the present disclosure; and

FIG. 14 is an illustrative cross-sectional view taken along line D-D of FIG. 13.

### DETAILED DESCRIPTION

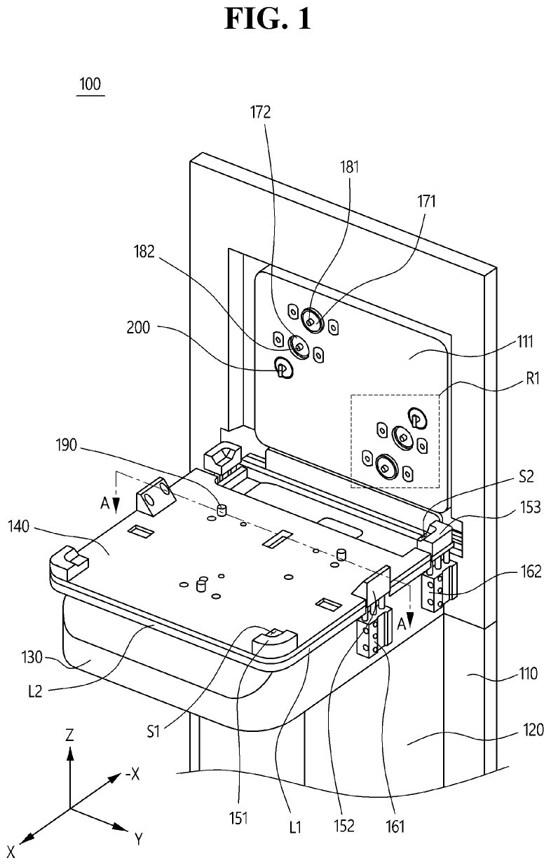

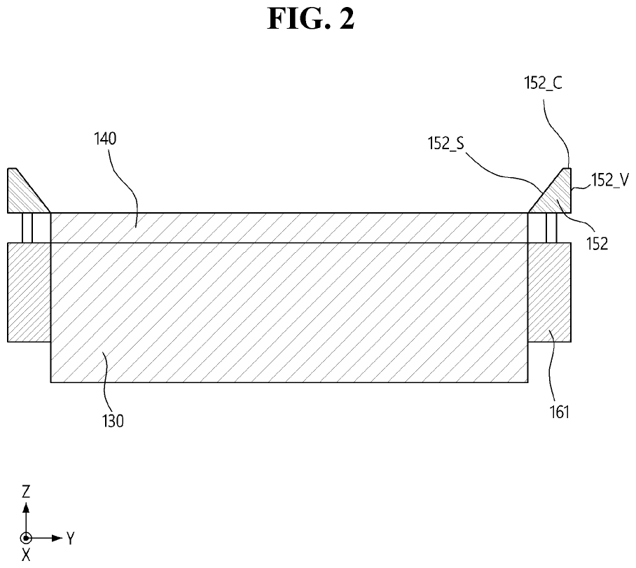

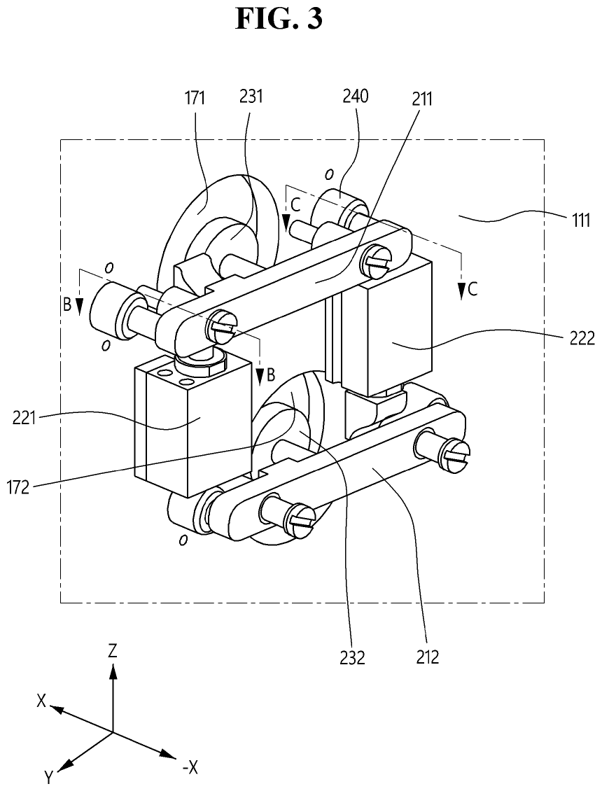

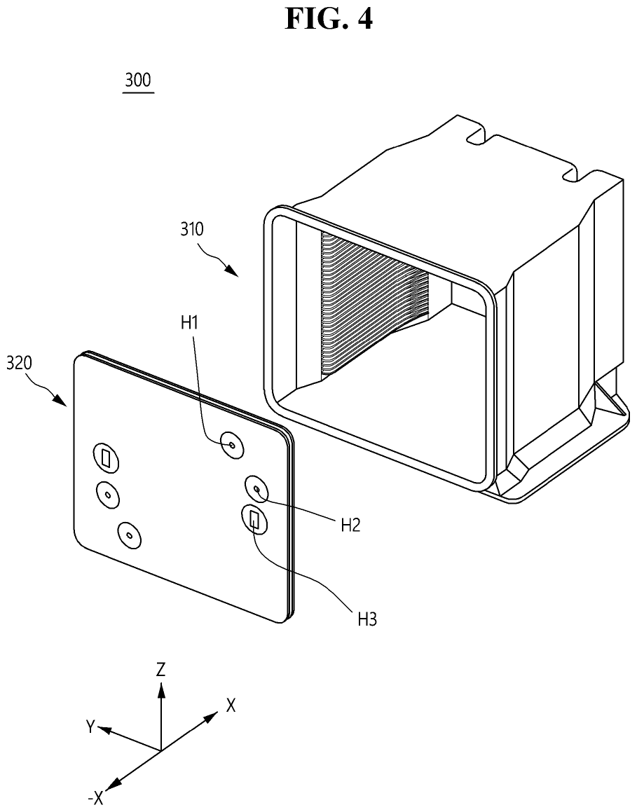

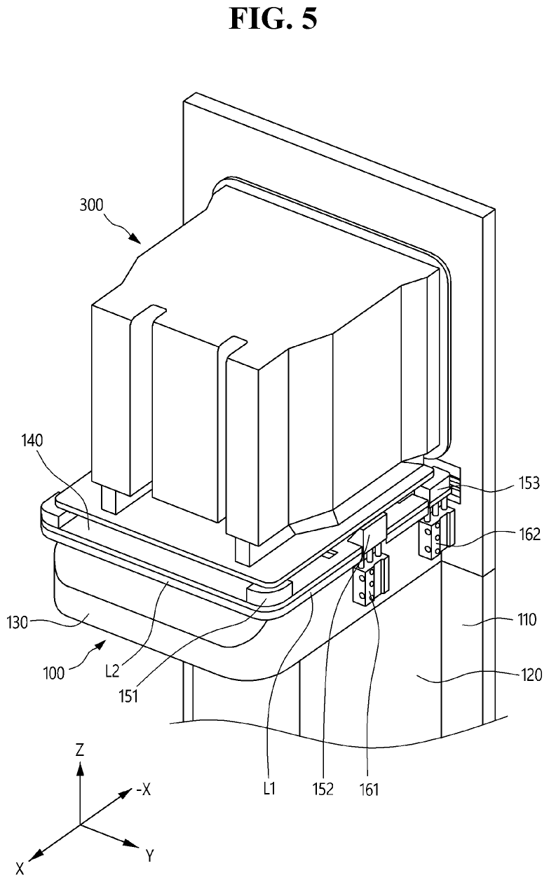

FIG. 1 is a view for describing a semiconductor transfer device according to some embodiments of the present disclosure. FIG. 2 is an illustrative cross-sectional view taken along line A-A of FIG. 1. FIG. 3 is an illustrative enlarged view of a rear surface of portion R1 of FIG. 1. FIG. 4 is an illustrative view for describing a semiconductor transfer container. FIG. 5 is an illustrative view for describing the semiconductor transfer container accommodated in the semiconductor transfer device according to some embodiments of the present disclosure.

Referring to FIGS. 1 to 5, a semiconductor transfer device 100 may include a vertical extension part 110, a support part 120, a horizontal extension part 130, a horizontal plate 140, first-type guide parts or first guide parts 151, second-type guide parts or second guide parts 152, third-type guide parts or third guide parts 153, a first guide cylinder 161, a second guide cylinder 162, first adsorption parts 171, second adsorption parts 172, first pins 181, second pins 182, vertical pins 190, grip parts 200, a first bracket 211, a second bracket 212, a first vertical cylinder 221, a second vertical cylinder 222, a first connection member 231, a second connection member 232, and balancing members 240.

The vertical extension part 110 may extend in a third direction Z. The third direction Z may cross a first direction X and a second direction Y (e.g., the third direction Z may be perpendicular to the first direction X and/or the second direction Y). The vertical extension part 110 may include a plane having an arbitrary straight line in the first direction X as a normal line.

The vertical extension part 110 may include a first surface and a second surface opposite to each other in the first direction X. The second direction Y may cross the first direction X (e.g., the second direction Y may be perpendicular to the first direction X). The horizontal extension part 130 may be installed on the first surface of the vertical extension part 110. The first vertical cylinder 221 and the second vertical cylinder 222 may be installed on the second surface of the vertical extension part 110.

The vertical extension part 110 may have a rectangular parallelepiped shape, but is not limited thereto. For example, the vertical extension part 110 may have a cylindrical shape.

The vertical extension part 110 may include a vertical plate 111. The vertical plate 111 may extend in the third direction Z. The vertical plate 111 may include surfaces opposite to each other in the first direction X. One surface of the vertical plate 111 may be the same as the first surface of the vertical extension part 110. The other surface of the vertical plate 111 may be the same as the second surface of the vertical extension part 110.

The vertical plate 111 may be movable in the third direction Z.

The support part 120 may extend in the third direction Z. The support part 120 may be installed on the first surface of the vertical extension part 110. The support part 120 may be in contact with the first surface of the vertical extension part 110.

A length or width of the support part 120 in the second direction Y may be smaller than a length or width of the vertical extension part 110 in the second direction Y. A length of the support part 120 in the third direction Z may be smaller than a length of the vertical extension part 110 in the third direction Z.

The support part 120 may withstand a load of an object seated on an upper surface of the support part 120. For example, even though the semiconductor transfer device 100 is seated on the upper surface of the support part 120, the support part 120 may support the semiconductor transfer device 100.

The horizontal extension part 130 may extend from the first surface of the vertical extension part 110. The horizontal extension part 130 may be in contact with the first surface of the vertical extension part 110.

The horizontal extension part 130 may be installed on the upper surface of the support part 120. The horizontal extension part 130 may be in contact with the upper surface of the support part 120.

The horizontal extension part 130 may extend in the first direction X. A length of the horizontal extension part 130 in the first direction X may be greater than a length of the support part 120 in the first direction X. A length or width of the horizontal extension part 130 in the second direction Y may be the same as the length or width of the support part 120 in the second direction Y.

The horizontal extension part 130 may have a pillar shape in which it extends in the first direction X, but is not limited thereto.

The horizontal extension part 130 may include a third surface and a fourth surface opposite to each other in the second direction Y.

The first guide cylinder 161 and the second guide cylinder 162 may be installed on the third surface of the horizontal extension part 130. A structure corresponding to the first guide cylinder 161 and a structure corresponding to the second guide cylinder 162 may also be installed on the fourth surface of the horizontal extension part 130. The phrase “structure corresponding to” as used herein refers to a substantially identical structure or a structure performing substantially the same function.

The horizontal extension part 130 may be supported by the support part 120.

The horizontal plate 140 may be installed on the horizontal extension part 130. The horizontal plate 140 may include a plane having an arbitrary straight line in the third direction Z as a normal line.

The horizontal plate 140 may be supported by the horizontal extension part 130.

The horizontal plate 140 may include a first edge L1 extending in the first direction X along a circumference of the horizontal plate 140. The horizontal plate 140 may include a second edge L2 extending in the second direction Y along the circumference of the horizontal plate 140. A point at which the first edge L1 and the second edge L2 cross each other or intersect may be a corner.

A guide part may include the first-type guide parts 151, the second-type guide parts 152, and the third-type guide parts 153. A relative positional relationship between the first-type guide parts 151, the second-type guide parts 152, and the third-type guide parts 153 may be changed. In addition, specific shapes of the first-type guide parts 151, the second-type guide parts 152, and the third-type guide parts 153 are not limited to those illustrated in the drawings.

The second-type guide parts 152 and the third-type guide parts 153 may be controlled by a controller commanding their movement ranges and movement directions.

The first-type guide part 151 may be installed on the horizontal plate 140. The first-type guide part 151 may be fixed onto the horizontal plate 140. The first-type guide part 151 may be installed on the horizontal plate 140 including at the corner of the horizontal plate 140. The first-type guide part 151 may be in contact with an upper surface of the horizontal plate 140.

A first groove S1 may be an empty space formed on the first guide part 151. The first groove S1 may have a shape in which it is recessed downwardly from an upper surface of the first guide part 151. A shape of the first-type guide part 151 in a portion recessed by the first groove S1 may be a curved surface. A shape of the first groove S1 illustrated in FIG. 1 is an illustrative shape in which a semiconductor transfer container or wafer transfer device 300 may be seated, and a shape of the first groove S1 is not limited to that illustrated in FIG. 1.

The semiconductor transfer container 300 may be supported by the first-type guide part 151. The semiconductor transfer container 300 may be seated on the portion of the first-type guide part 151 recessed by the first groove S1. A portion of the first-type guide part 151 extending to the upper surface thereof that is not recessed by the first groove S1 may fix the semiconductor transfer container 300 so that the semiconductor transfer container 300 is not separated from the portion of the first-type guide part 151 recessed by the first groove S1. The first-type guide part 151 may include the recessed portion or surface (e.g., seat) and a wall extending upwardly therefrom and terminating at the upper surface of the first-type guide part 151. The semiconductor transfer container 300 may be on the recessed portion and held in place by the wall.

The second-type guide part 152 may penetrate through the horizontal plate 140. The second-type guide part 152 may be movable within a predetermined range in the third direction Z. In other words, the second-type guide part 152 may move up and down within a predetermined range. The second-type guide part 152 may receive power provided by a first guide cylinder 161 to be described below.

The first-type guide part 151 may be spaced apart from the second-type guide part 152 in the first direction X. In other words, the second-type guide part 152 may be spaced apart from the first-type guide part 151 in a fourth direction −X opposite to the first direction X.

The second-type guide part 152 may have a pillar shape. For example, the second-type guide part 152 may have a triangular prism shape.

The second-type guide part 152 may include an inclined surface 152_S, a first vertical surface 152_V, and a first connection surface 152_C.

The inclined surface 152_S may be a plane forming a predetermined angle with the upper surface of the horizontal plate 140. For example, the inclined surface 152_S may form an acute angle with the upper surface of the horizontal plate 140.

The first vertical surface 152_V may be a surface parallel to the third surface of the horizontal extension part 130.

The first connection surface 152_C may be a surface parallel to the upper surface of the horizontal plate 140.

The inclined surface 152_S may share one edge with the first connection surface 152_C, and the first vertical surface 152_V may share the other edge with the first connection surface 152_C. Consequently, the inclined surface 152_S and the first vertical surface 152_V may be connected to each other through the first connection surface 152_C.

The semiconductor transfer container 300 may be seated on the horizontal plate 140 by sliding along the inclined surface 152_S.

The third-type guide part 153 may not be in contact with the horizontal plate 140. The third-type guide part 153 may be movable within a predetermined range in the third direction Z. In other words, the third-type guide part 153 may move up and down within a predetermined range. The third-type guide part 153 may receive power provided by a second guide cylinder 162 to be described below.

The third-type guide part 153 may be spaced apart from the second-type guide part 152 and the first-type guide part 151 in the first direction X. In other words, the third-type guide part 153 may be spaced apart from the first-type guide part 151 in the fourth direction −X. In addition, the third-type guide part 153 may be spaced apart from the second-type guide part 152 in the fourth direction −X.

The first-type guide part 151 and the third-type guide part 153 may be spaced apart from each other in opposite directions based on the second-type guide part 152. In other words, the second-type guide part 152 may be positioned between the first-type guide part 151 and the third-type guide part 153.

A second groove S2 may be an empty space formed on the third guide part 153. The second groove S2 may have a shape in which it is recessed downwardly from an upper surface of the third guide part 153. A shape of the third-type guide part 153 in a portion recessed by the second groove S2 may be a curved surface. A shape of the second groove S2 illustrated in FIG. 1 is an illustrative shape in which the semiconductor transfer container 300 may be seated, and a shape of the second groove S2 is not limited to that illustrated in FIG. 1. The third-type guide part 153 may include the recessed portion or surface (e.g., seat) and a wall extending upwardly therefrom and terminating at the upper surface of the third-type guide part 153. The semiconductor transfer container 300 may be on the recessed portion and held in place by the wall.

The first guide cylinder 161 may be formed on the third surface of the horizontal extension part 130. A structure corresponding to the first guide cylinder 161 may be installed on the fourth surface of the horizontal extension part 130.

The first guide cylinder 161 may transmit power to the second-type guide part 152. For example, the first guide cylinder 161 may transmit power to the second-type guide part 152 through a piston positioned inside the first guide cylinder 161.

The first guide cylinder 161 may move the second-type guide part 152 in the third direction Z. For example, when the first guide cylinder 161 applies pressure to a lower surface of the second-type guide part 152, the second-type guide part 152 may be moved upward.

The first guide cylinder 161 may be connected to the second-type guide part 152. The second-type guide part 152 may be directly connected to the first guide cylinder 161 or may be connected to the first guide cylinder 161 through an additional component positioned between the first guide cylinder 161 and the second-type guide part 152.

The second guide cylinder 162 may be formed on the third surface of the horizontal extension part 130. A structure corresponding to the second guide cylinder 162 may be installed on the fourth surface of the horizontal extension part 130.

The second guide cylinder 162 may transmit power to the third-type guide part 153. For example, the second guide cylinder 162 may transmit power to the third-type guide part 153 through a piston positioned inside the second guide cylinder 162.

The second guide cylinder 162 may move the third-type guide part 153 in the third direction Z. For example, when the second guide cylinder 162 applies pressure to a lower surface of the third-type guide part 153, the third-type guide part 153 may be moved upward.

The second guide cylinder 162 may be connected to the third-type guide part 153. The third-type guide part 153 may be directly connected to the second guide cylinder 162 or may be connected to the second guide cylinder 162 through an additional component positioned between the second guide cylinder 162 and the third-type guide part 153.

The first adsorption part or first suction part 171 may adsorb or suction a lid part or lid 320 of the semiconductor transfer container 300 seated on the semiconductor transfer device 100. The first adsorption part 171 may adsorb the lid part 320 and be then moved in the fourth direction −X to detach the lid part 320 from a body part or body 310.

Conversely, the first adsorption part 171 may mount the lid part 320 on the body part 310 seated on the semiconductor transfer device 100. The first adsorption part 171 may adsorb the lid part 320 and be then moved in the first direction X to attach the lid part 320 to the body part 310.

When the first adsorption part 171 is attached to the lid part 320, an air pressure difference between a portion that is surrounded by the first adsorption part 171 and the lid part 320 and a portion that is not surrounded by the first adsorption part 171 and the lid part 320 may occur. It may be adjusted whether or not the first adsorption part 171 performs adsorption or suction using such an air pressure difference.

The first adsorption part 171 may be made of a rubber component, but is not limited thereto.

The first adsorption part 171 may have a hollow truncated cone shape, but is not limited thereto.

The second adsorption part or second suction part 172 may adsorb or suction the lid part 320 of the semiconductor transfer container 300 seated on the semiconductor transfer device 100. The second adsorption part 172 may adsorb the lid part 320 and be then moved in the fourth direction −X to detach the lid part 320 from the body part 310.

Conversely, the second adsorption part 172 may mount the lid part 320 on the body part 310 seated on the semiconductor transfer device 100. The second adsorption part 172 may adsorb the lid part 320 and be then moved in the first direction X to attach the lid part 320 to the body part 310.

The first adsorption part 171 and the second adsorption part 172 may penetrate or extend into or through the vertical extension part 110. More specifically, the first adsorption part 171 and the second adsorption part 172 may penetrate or extend into or through the vertical plate 111 of the vertical extension part 110.

Movement degrees of the first adsorption part 171 and the second adsorption part 172 in the first direction X may be different from each other. For example, the first adsorption part 171 may protrude from the first surface, and the second adsorption part 172 may protrude from the second surface.

The first adsorption part 171 and the second adsorption part 172 may be spaced apart from each other in the second direction Y. In addition, the first adsorption part 171 and the second adsorption part 172 may be spaced apart from each other in the third direction Z.

It may be assumed that the center of the vertical plate 111 is positioned in the middle of the vertical plate 111. A structure corresponding to the first adsorption part 171 and the second adsorption part 172 may be symmetrical to each other with respect to the center of the vertical plate 111. A structure corresponding to the first adsorption part 171 and the second adsorption part 172 may be symmetrical to each other with respect to the center of the vertical plate 111.

It has been illustrated in FIG. 1 that the number of each of first adsorption parts 171 and second adsorption parts 172 is two, but the number of each of first adsorption parts 171 and second adsorption parts 172 is not limited to two.

Positions of the first and second adsorption parts 171 and 172 are not limited to specific positions of the vertical extension part 110, but the first and second adsorption parts 171 and 172 may be disposed at positions different from those illustrated in the drawings depending on a shape of the semiconductor transfer container 300.

The first adsorption part 171 and the second adsorption part 172 may or may not be used depending on a type of the semiconductor transfer container 300 accommodated in the semiconductor transfer device 100. In other words, the first adsorption part 171 and the second adsorption part 172 may perform different operations.

As an example, when an A-type semiconductor transfer container (e.g., a front opening unified pod (FOUP)) is accommodated in the semiconductor transfer device 100, the first adsorption part 171 may adsorb the lid part 320, and the second adsorption part 172 may not adsorb the lid part 320.

As another example, when a B-type semiconductor transfer container (e.g., a multi application carrier (MAC)) is accommodated in the semiconductor transfer device 100, the second adsorption part 172 may adsorb the lid part 320, and the first adsorption part 171 may not adsorb the lid part 320.

The first pin 181 may extend from the first adsorption part 171 in the first direction X. The first pin 181 may have a shape in which it protrudes from the first adsorption part 171.

The first pin 181 may fix the lid part 320 of the semiconductor transfer container 300. The first pin 181 may be physically coupled to the lid part 320 of the semiconductor transfer container 300. For example, the first pin 181 may penetrate through a first hollow or first recess H1 of the lid part 320 to fix the lid part 320.

The second pin 182 may extend from the second adsorption part 172 in the first direction X. The second pin 182 may be physically coupled to the lid part 320 of the semiconductor transfer container 300. For example, the second pin 182 may penetrate through a second hollow or second recess H2 of the lid part 320 to fix the lid part 320.

The grip part 200 may protrude or extend from the first surface of the vertical plate 111. It has been illustrated in FIG. 1 that the grip part 200 extends in the third direction Z, but is not limited thereto.

The grip part 200 may open or close the lid part 320 of the semiconductor transfer container 300. The grip part 200 may penetrate through a grip hole H3 of the lid part 320. The grip part 200 may rotate in a state in which it penetrates through the grip hole H3 of the lid part 320.

The lid part 320 may be fixed to or detached from the body part 310, depending on a direction in which the grip part 200 rotates. For example, when the grip part 200 rotates in a clockwise direction, the lid part 320 may be fixed to the body part 310, and when the grip part 200 rotates in a counterclockwise direction, the lid part 320 may be detached from the body part 310.

For convenience of explanation, it has been illustrated that the number of grip parts 200 is two, but the number of grip parts 200 is not limited to two.

Positions of the grip parts 200 are not limited to specific positions of the vertical extension part 110, and the grip parts 200 may be disposed at positions different from those illustrated in the drawings depending on the shape of the semiconductor transfer container 300.

The vertical pin 190 may protrude or extend from the upper surface of the horizontal plate 140. The vertical pin 190 may fix the body part 310 of the semiconductor transfer container 300. The vertical pin 190 may be physically coupled to the body part 310 of the semiconductor transfer container 300. For example, the vertical pin 190 may be engaged with one structure (e.g., recess) positioned on a lower surface of the body part 310 to fix the body part 310.

The first bracket 211 may be disposed on the second surface of the vertical plate 111. The first bracket 211 may extend in the second direction Y. The first bracket 211 may be spaced apart from the second surface of the vertical plate 111 in the first direction X.

The second bracket 212 may be disposed on the second surface of the vertical plate 111. The second bracket 212 may extend in the second direction Y. The second bracket 212 may be spaced apart from the second surface of the vertical plate 111 in the first direction X.

The first bracket 211 and the second bracket 212 may be spaced apart from each other in the third direction Z.

A length of the first bracket 211 in the second direction Y may be the same as a length of the second bracket 212 in the second direction Y.

The first bracket 211 and the second bracket 212 may be movable in the first direction X.

The first vertical cylinder 221 may extend in the third direction Z. The first vertical cylinder 221 may be positioned on the second surface of the vertical plate 111. The first vertical cylinder 221 may be in contact with the second surface of the vertical plate 111.

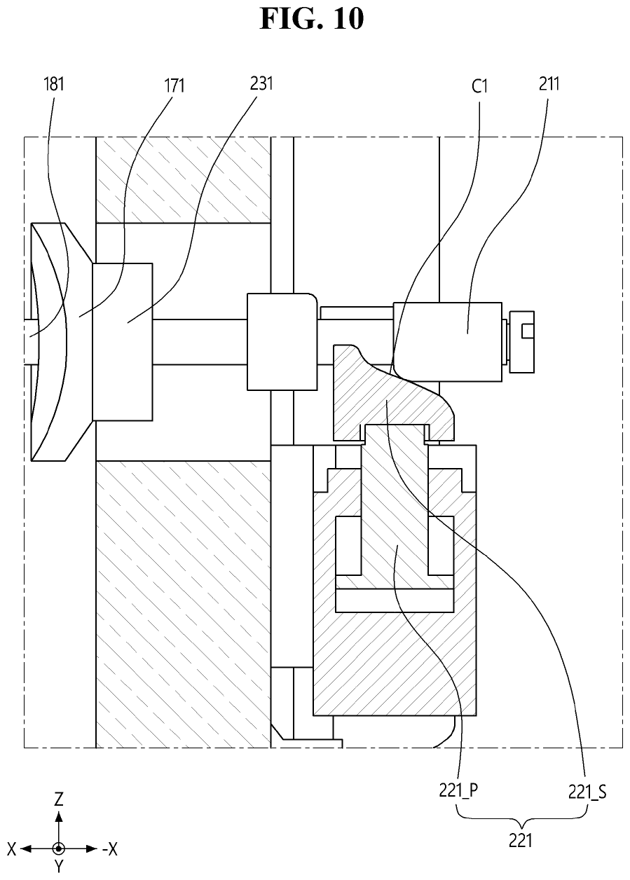

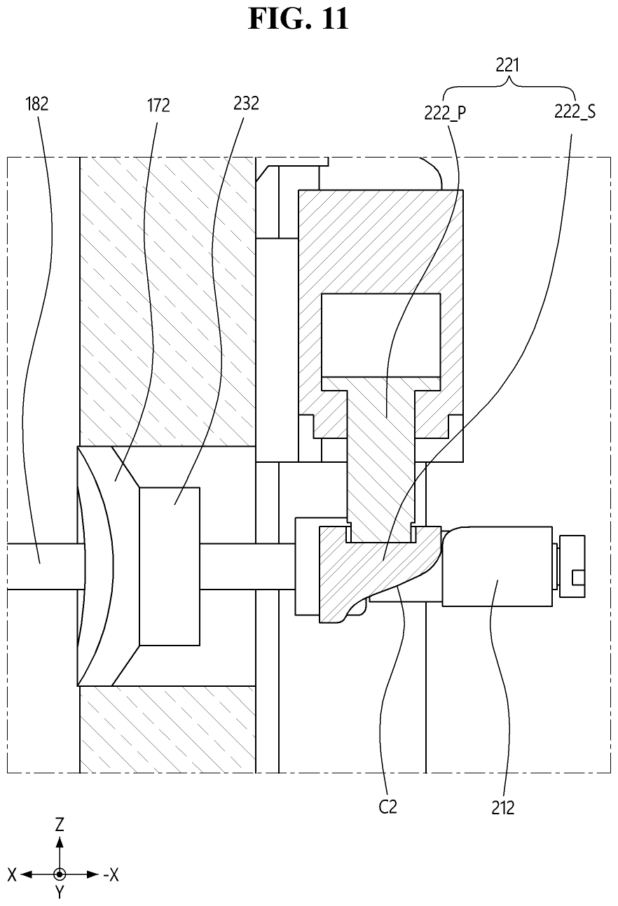

The first vertical cylinder 221 may transmit power to the first bracket 211 so that the first bracket 211 is moved in the first direction X. A detailed movement principle will be described below with reference to FIGS. 10 and 11.

The second vertical cylinder 222 may extend in the third direction Z. The second vertical cylinder 222 may be positioned on the second surface of the vertical plate 111. The second vertical cylinder 222 may be in contact with the second surface of the vertical plate 111.

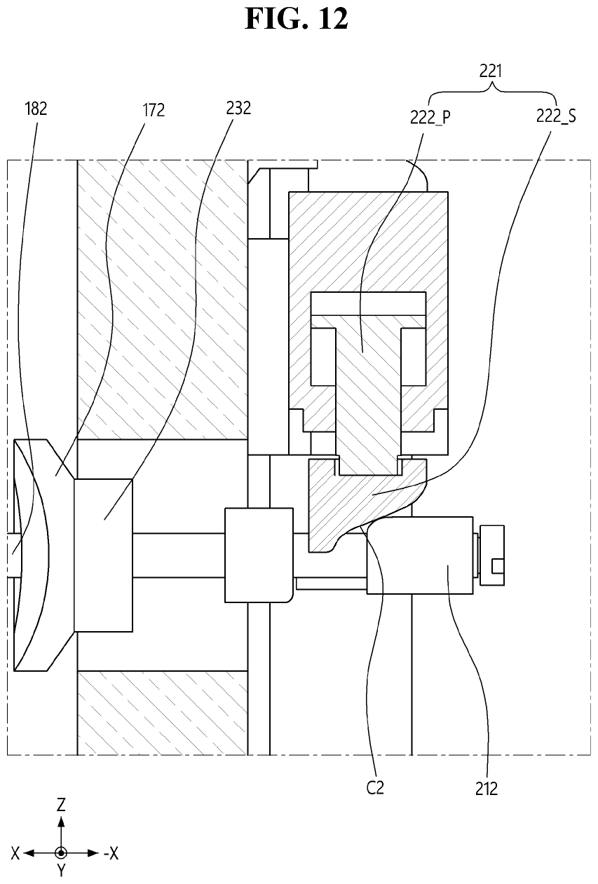

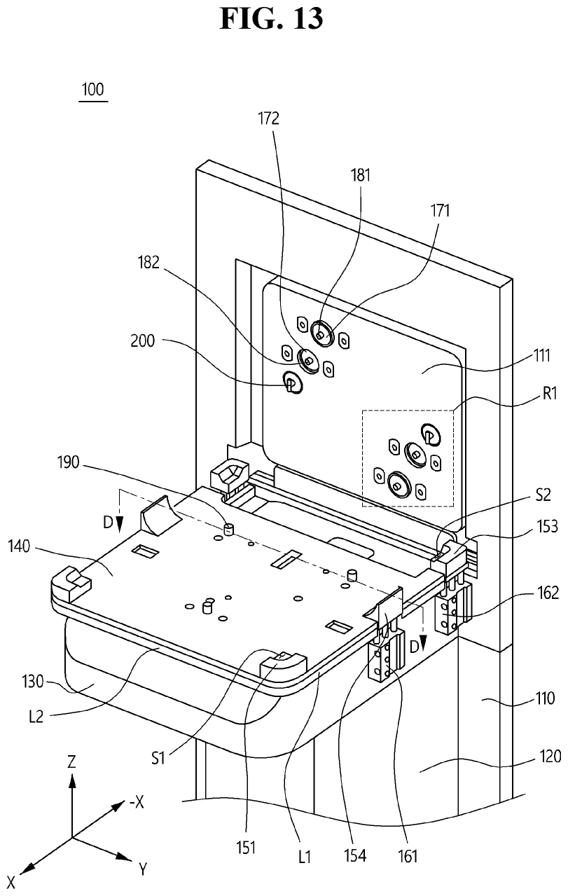

The second vertical cylinder 222 may transmit power to the second bracket 212 so that the second bracket 212 is moved in the first direction X. A detailed movement principle will be described below with reference to FIGS. 12 and 13.

The first connection member 231 may connect the first adsorption part 171 and the first bracket 211 to each other.

The second connection member 232 may connect the second adsorption part 172 and the second bracket 212 to each other.

The balancing member 240 may maintain balance when the first bracket 211 or the second bracket 212 is moved. More specifically, the first bracket 211 or the second bracket 212 receives the power transmitted by the first vertical cylinder 221 or the second vertical cylinder 222 in order to be moved in the first direction X. In this case, the power transmitted by the first vertical cylinder 221 or the second vertical cylinder 222 may be evenly transmitted to the first bracket 211 or the second bracket 212. Accordingly, the first bracket 211 or the second bracket 212 may be moved in a state in which it is parallel to the second surface.

The balancing member 240 may be on the second surface of the vertical plate 111. It has been illustrated in FIG. 4 that four balancing member 240 are used, but the present disclosure is not limited thereto.

Referring to FIG. 4 again, the semiconductor transfer container 300 may include the body part 310 and the lid part 320.

A shape of the semiconductor transfer container 300 illustrated in FIG. 4 is only an example, and a shape of the semiconductor transfer container 300 is not limited thereto. Accordingly, the shape of the semiconductor transfer container 300 may be modified into various shapes in which the semiconductor transfer container 300 may be accommodated in the semiconductor transfer device 100. In addition, the semiconductor transfer container 300 illustrated in FIG. 4 may include other components in addition to the body part 310 and the lid part 320.

The body part 310 may be a hollow housing. A plurality of wafers may be disposed inside the body part 310.

The lid part 320 may have a plate shape. The lid part 320 may be detached from or attached to a front surface of the body part 310.

The lid part 320 may include the first hollows H1, the second hollows H2, and the grip holes H3.

The first hollow H1 may be disposed on one surface of the lid part 320. The first pin 181 may be inserted into the first hollow H1.

The second hollow H2 may be disposed on one surface of the lid part 320. The second pin 182 may be inserted into the second hollow H2. The first hollow H1 and the second hollow H2 may be spaced apart from each other in the second direction Y. In addition, the first hollow H1 and the second hollow H2 may be spaced apart from each other in the third direction Z.

The grip hole H3 may be disposed on one surface of the lid part 320. The grip part 200 may be inserted into the grip hole H3. The second hollow H2 and the grip hole H3 may be spaced apart from each other in the second direction Y. In addition, the second hollow H2 and the grip hole H3 may be spaced apart from each other in the third direction Z.

The second hollow H2 may be positioned between the first hollow H1 and the grip hole H3.

It may be assumed that the center of the lid part 320 is positioned in the middle of the lid part 320. Two first hollows H1 may be symmetrical to each other with respect to the center of the lid part 320. Two second hollows H2 may be symmetrical to each other with respect to the center of the lid part 320. Two grip holes H3 may be symmetrical to each other with respect to the center of the lid part 320.

For convenience of explanation, it has been illustrated that the number of each of first hollows H1, second hollows H2, and grip holes H3 is two, but the number of each of first hollows H1, second hollows H2, and grip holes H3 is not limited to two.

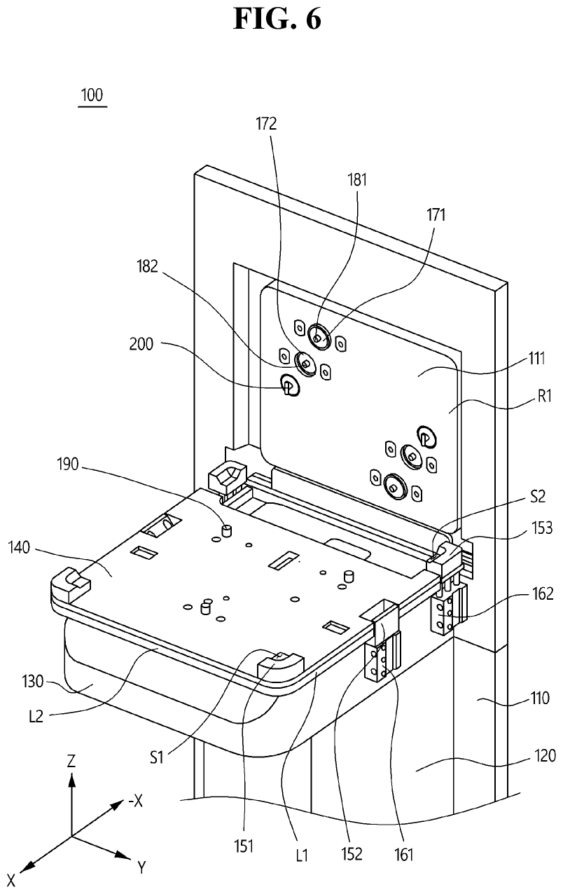

FIGS. 6 to 8 are views for describing a guide part of the semiconductor transfer device according to some embodiments of the present disclosure.

Referring to FIG. 6, the first guide cylinder 161 may move the second-type guide part 152 downward, and the second guide cylinder 162 may move the third-type guide part 153 upward.

The second-type guide part 152 may be in contact with the first guide cylinder 161. The second-type guide part 152 may be supported by the first guide cylinder 161.

The third-type guide part 153 may not be in contact with the second guide cylinder 162. The third-type guide part 153 may protrude or extend from the upper surface of the horizontal plate 140.

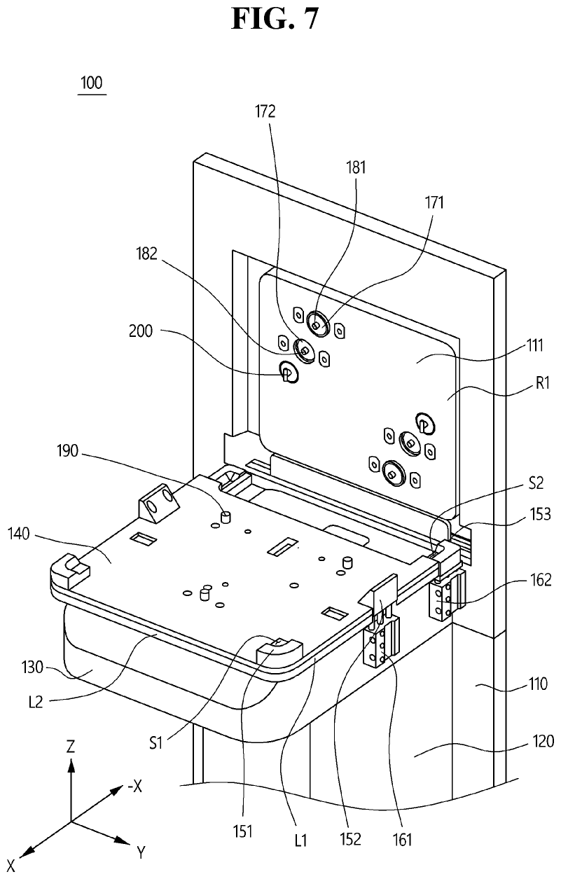

Referring to FIG. 7, the first guide cylinder 161 may move the second-type guide part 152 upward, and the second guide cylinder 162 may move the third-type guide part 153 downward.

The second-type guide part 152 may not be in contact with the first guide cylinder 161. The second-type guide part 152 may protrude or extend from the upper surface of the horizontal plate 140.

The third-type guide part 153 may be in contact with the second guide cylinder 162. The third-type guide part 153 may be supported by the second guide cylinder 162.

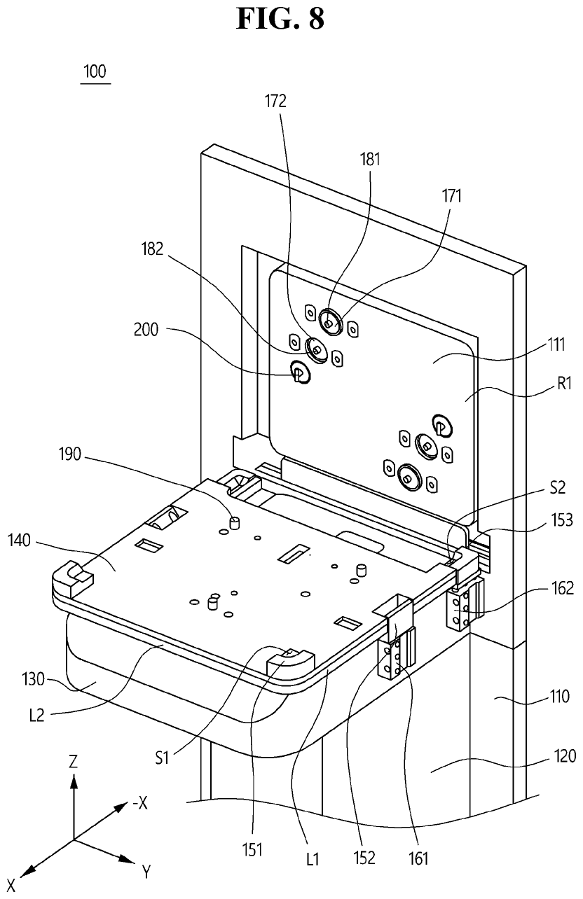

Referring to FIG. 8, the first guide cylinder 161 may move the second-type guide part 152 downward, and the second guide cylinder 162 may move the third-type guide part 153 downward.

The second-type guide part 152 may be in contact with the first guide cylinder 161. The second-type guide part 152 may be supported by the first guide cylinder 161.

The third-type guide part 153 may be in contact with the second guide cylinder 162. The third-type guide part 153 may be supported by the second guide cylinder 162.

FIGS. 6 to 8 are views for describing different operation modes of the semiconductor transfer device 100. The operation modes of the semiconductor transfer device 100 are not limited to those illustrated in FIGS. 6 to 8. For example, both the first guide cylinder 161 and the second guide cylinder 162 may be moved upward, such that both the second-type guide part 152 and the third guide part 153 may move upward.

If the semiconductor transfer device 100 may accommodate only one type of semiconductor transfer container 300, a different semiconductor transfer device 100 may be required for each semiconductor transfer container 300. Accordingly, a plurality of semiconductor transfer devices 100 may be required in order to accommodate different semiconductor transfer containers 300.

The semiconductor transfer device 100 according to some embodiments of the present disclosure may accommodate different semiconductor transfer containers 300 in each operation mode. Movement degrees of the second-type guide part 152 and the third-type guide part 153 may be different from each other depending on a type of the semiconductor transfer container 300. In other words, the semiconductor transfer device 100 may accommodate all types of semiconductor transfer containers 300 by changing the operation mode depending on the type of the semiconductor transfer container 300. In conclusion, even though types of semiconductor transfer containers 300 vary, all types of semiconductor transfer containers 300 may be accommodated using one semiconductor transfer device 100.

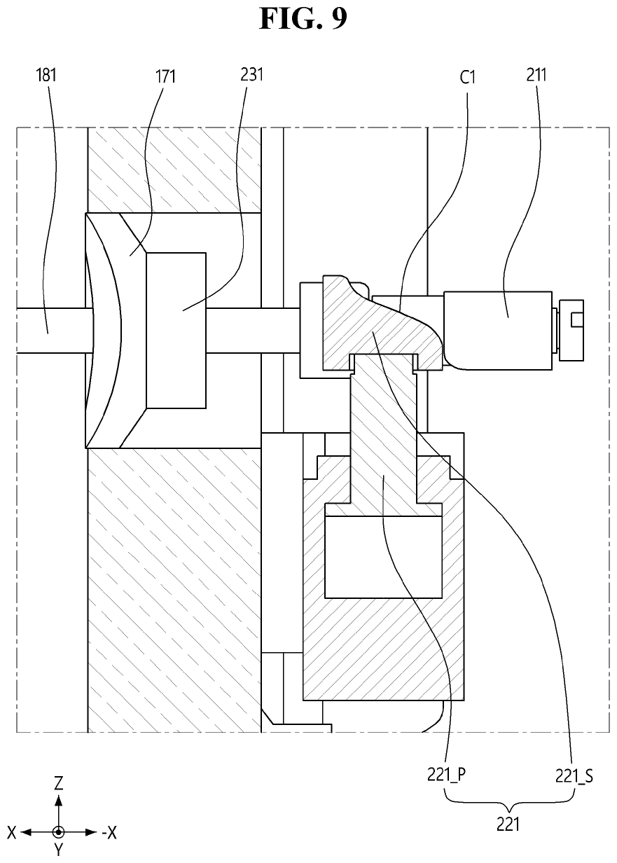

FIGS. 9 to 12 are cross-sectional views for describing an operating method of the semiconductor transfer device according to some embodiments of the present disclosure.

An operating method of the semiconductor transfer device 100 will be described with reference to FIGS. 9 and 10, which are cross-sectional views taken along line B-B of FIG. 3.

Referring to FIGS. 9 and 10, the first vertical cylinder 221 may include a first piston 221_P and a first slope part 221_S.

When the first vertical cylinder 221 is moved in an upward direction, the first piston 221_P and the first slope part 221_S may move upward. Conversely, when the first vertical cylinder 221 is moved in a downward direction, the first piston 221_P and the first slope part 221_S may move downward.

The first bracket 211 may have a property that it moves in the first direction X from the second surface toward the first surface by an elastic material or a biasing member.

When the first piston 221_P and the first slope part 221_S move upward, the first bracket 211 may be in contact with a first curved surface C1 of the first slope part 221_S. When the first piston 221_P and the first slope part 221_S further move upward, the first bracket 211 may be pushed in a direction in which it becomes distant from the second surface of the vertical extension part 110 by the first slope part 221_S. Accordingly, the first bracket 211 may move in the direction in which it becomes distant from the second surface of the vertical extension part 110. In other words, the first bracket 211 may move in the fourth direction −X opposite to the first direction X.

The first bracket 211 is connected to the first adsorption part 171 by the first connection member 231. Accordingly, when the first bracket 211 becomes distant from the second surface, the first adsorption part 171 may also move in the direction in which it becomes distant from the second surface of the vertical extension part 110. In other words, the first adsorption part 171 may also move in the fourth direction −X.

Conversely, when the first piston 221_P and the first slope part 221_S move downward, the first bracket 211 may not be pushed by the first slope part 221_S. Since the first bracket 211 may have the property that it moves in the first direction X by the elastic material, the first bracket 211 may move in the first direction X.

Since the first bracket 211 is connected to the first adsorption part 171 by the first connection member 231, the first bracket 211 may move in the first direction X.

An operating method of the semiconductor transfer device will be described with reference to FIGS. 11 and 12, which are cross-sectional views taken along line C-C of FIG. 3.

Referring to FIGS. 11 and 12, the second vertical cylinder 222 may include a second piston 222_P and a second slope part 222_S.

When the second vertical cylinder 222 is moved in the downward direction, the second piston 222_P and the second slope part 222_S may move downward. Conversely, when the second vertical cylinder 222 is moved in the upward direction, the second piston 222_P and the second slope part 222_S may move upward.

The second bracket 212 may have a property that it moves in the first direction X from the second surface toward the first surface by an elastic material or biasing member.

When the second piston 222_P and the second slope part 222_S move downward, the second bracket 212 may be in contact with a second curved surface C2 of the second slope part 222_S. When the second piston 222_P and the second slope part 222_S further move downward, the second bracket 212 may be pushed in a direction in which it becomes distant from the second surface of the vertical extension part 110 by the second slope part 222_S. Accordingly, the second bracket 212 may move in the direction in which it becomes distant from the second surface of the vertical extension part 110. In other words, the second bracket 212 may move in the fourth direction −X opposite to the first direction X.

The second bracket 212 is connected to the second adsorption part 172 by the second connection member 232. Accordingly, when the second bracket 212 becomes distant from the second surface of the vertical extension part 110, the second adsorption part 172 may also move in the direction in which it becomes distant from the second surface. In other words, the second adsorption part 172 may also move in the fourth direction −X.

Conversely, when the second piston 222_P and the second slope part 222_S move upward, the second bracket 212 may not be pushed by the second slope part 222_S. Since the second bracket 212 may have the property that it moves in the first direction X by the clastic material, the second bracket 212 may move in the first direction X.

Since the second bracket 212 is connected to the second adsorption part 172 by the second connection member 232, the second bracket 212 may move in the first direction X.

In order to move the first adsorption part 171 or the second adsorption part 172 in the first direction X or the fourth direction −X, a cylinder extending in the first direction X may be used. However, when the cylinder extending in the first direction X is used, the cylinder extending in the first direction X may interfere with a structure positioned on the second surface of the vertical extension part 110. For example, a transport robot gripping and transporting a wafer may exist on the second surface of the vertical extension part 110. When the cylinder extending in the first direction X is used, interference may occur between the cylinder extending in the first direction X and the transport robot.

Referring to FIGS. 3 and 9 to 12 again, an occupied space may be reduced by disposing the first vertical cylinder 221 and the second vertical cylinder 222 vertically. More specifically, the first vertical cylinder 221 or the second vertical cylinder 222 may extend in the third direction Z, and thus, an occupied space may be decreased as compared with a case of using the cylinder extending in the first direction X. As a result, when the first vertical cylinder 221 or the second vertical cylinder 222 is used, the first vertical cylinder 221 or the second vertical cylinder 222 may not interfere with the structure positioned on the second surface of the vertical extension part 110.

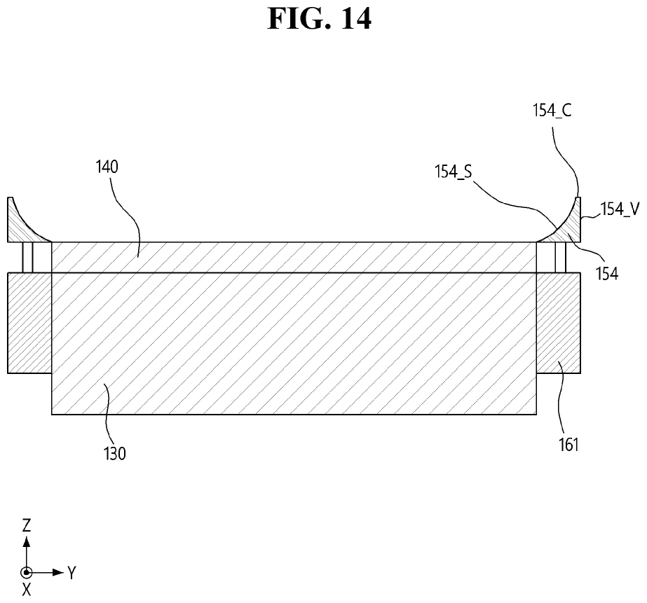

FIG. 13 is a view for describing a semiconductor transfer device according to some embodiments of the present disclosure. FIG. 14 is an illustrative cross-sectional view taken along line D-D of FIG. 13. For convenience of explanation, contents different from those described with reference to FIGS. 1 to 5 will be mainly described.

A fourth-type guide part 154 may penetrate through the horizontal plate 140. The fourth-type guide part 154 may be movable within a predetermined range in the third direction Z. In other words, the fourth-type guide part 154 may move up and down within a predetermined range. The fourth-type guide part 154 may receive power provided by the first guide cylinder 161.

The fourth-type guide part 154 may be spaced apart from the first-type guide part 151 in the first direction X. In other words, the fourth-type guide part 154 may be spaced apart from the first-type guide part 151 in the fourth direction −X opposite to the first direction X.

The first-type guide part 151 and the third-type guide part 153 may be spaced apart from each other in opposite directions based on the fourth-type guide part 154. In other words, the fourth-type guide part 154 may be positioned between the first-type guide part 151 and the third-type guide part 153.

The fourth-type guide part 154 may have a pillar shape, and include a concave surface 154_S, a second vertical surface 154_V, and a second connection surface 154_C.

The concave surface 154_S may have a concave shape. The concave surface 154_S may be a surface formed by concavely recessing one surface of a triangular prism shape. The concave surface 154_S is a concavely recessed surface, and may be a curved surface.

The second vertical surface 154_V may be a surface parallel to the third surface of the horizontal extension part 130.

The second connection surface 154_C may be a surface parallel to the upper surface of the horizontal plate 140. The concave surface 154_S may share one edge with the second connection surface 154_C, and the second vertical surface 154_V may share the other edge with the second connection surface 154_C. Consequently, the concave surface 154_S and the second vertical surface 154_V may be connected to each other through the second connection surface 154_C.

The semiconductor transfer container 300 may be seated on the horizontal plate 140 by sliding along the concave surface 154_S.

When the concave surface 154_S is used, impact transmitted to the semiconductor transfer container 300 during a process in which the semiconductor transfer container 300 slides along the concave surface 154_S may be decreased.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A semiconductor transfer device comprising:
a vertical extension part extending in a first direction and including a first surface and a second surface opposite to each other in a second direction crossing the first direction;
a support part on the first surface of the vertical extension part and extending in the first direction;
a horizontal plate on the support part and extending in the second direction, and including a corner at which a first edge extending in the second direction along a circumference of the horizontal plate and a second edge extending in a third direction crossing the first direction and the second direction along the circumference of the horizontal plate intersect; and
a first-type guide part extending from an upper surface of the horizontal plate at the corner.

2. The semiconductor transfer device of claim 1, further comprising a horizontal extension part between a lower surface of the horizontal plate and an upper surface of the support part, extending in the second direction, and including a third surface and a fourth surface opposite to each other in the third direction.

3. The semiconductor transfer device of claim 2, further comprising:
a first guide cylinder on the third surface of the horizontal extension part and configured to transmit power; and
a second-type guide part connected to the first guide cylinder and movable in the first direction.

4. The semiconductor transfer device of claim 3, wherein the second-type guide part is movable to extend through the horizontal plate.

5. The semiconductor transfer device of claim 3, further comprising:
a second guide cylinder on the third surface of the horizontal extension part, and spaced apart from the first guide cylinder in a fourth direction opposite to the second direction, and configured to transmit power; and
a third-type guide part connected to the second guide cylinder and movable in the first direction.

6. The semiconductor transfer device of claim 5, wherein a semiconductor transfer container is configured to be accommodated on the first-type guide part, the second-type guide part, and the third-type guide part.

7. The semiconductor transfer device of claim 1, further comprising:
a bracket on the second surface of the vertical extension part and extending in the third direction;
an adsorption part connected to the bracket and configured to adsorb a wafer transfer device; and
a pin extending from the adsorption part in the first direction and configured to fix the wafer transfer device,
wherein the adsorption part and the pin are movable in the second direction to extend through the vertical extension part in the second direction.

8. The semiconductor transfer device of claim 7, further comprising a vertical cylinder on the second surface of the vertical extension part and extending in the first direction,
wherein as a piston included in the vertical cylinder moves in the first direction, movement of the bracket in the second direction is adjusted.

9. A semiconductor transfer device comprising:
a vertical extension part extending in a first direction and including a first surface and a second surface opposite to each other in a second direction crossing the first direction;
a support part on the first surface of the vertical extension part and extending in the first direction;
a horizontal extension part on the support part and extending in the second direction, and including a third surface and a fourth surface opposite to each other in a third direction crossing the first direction and the second direction;
a first guide cylinder on the third surface of the horizontal extension part and configured to transmit power; and
a first-type guide part connected to the first guide cylinder and movable in the first direction,
wherein the first-type guide part includes a vertical surface parallel to the third surface and an inclined surface forming an acute angle with an upper surface of the horizontal extension part.

10. The semiconductor transfer device of claim 9, further comprising a horizontal plate on the upper surface of the horizontal extension part and extending in the second direction.

11. The semiconductor transfer device of claim 10, wherein the first-type guide part is movable to extend through the horizontal plate.

12. The semiconductor transfer device of claim 10, further comprising a second-type guide part extending from an upper surface of the horizontal plate at a corner of the horizontal plate,
and wherein the horizontal plate includes the corner at which a first edge extending in the second direction along a circumference of the horizontal plate and a second edge extending in the third direction along the circumference of the horizontal plate intersect.

13. The semiconductor transfer device of claim 9, further comprising:
a second guide cylinder on the third surface of the horizontal extension part and spaced apart from the first guide cylinder in a fourth direction opposite to the second direction, and configured to transmit power; and
a third-type guide part connected to the second guide cylinder and movable in the first direction.

14. The semiconductor transfer device of claim 9, further comprising:
a bracket on the second surface of the vertical extension part and extending in the third direction;
a suction part connected to the bracket and configured to suction a wafer transfer device;
a pin extending from the suction part in the first direction and configured to fix the wafer transfer device; and
a vertical cylinder on the second surface of the vertical extension part and extending in the first direction,
wherein the suction part and the pin are movable in the second direction to extend through the vertical extension part in the second direction, and
as a piston included in the vertical cylinder moves in the first direction, movement of the bracket in the second direction is adjusted.

15. A semiconductor transfer device comprising:
a vertical extension part extending in a first direction and including a first surface and a second surface opposite to each other in a second direction crossing the first direction;
a support part on the first surface of the vertical extension part and extending in the first direction;
a horizontal extension part on the support part and extending in the second direction, and including a third surface and a fourth surface opposite to each other in a third direction crossing the first direction and the second direction;
a first guide cylinder on the third surface of the horizontal extension part and configured to transmit power; and
a first-type guide part connected to the first guide cylinder and movable in the first direction,
wherein the first-type guide part includes a vertical surface parallel to the third surface and a concave surface between the vertical surface and the third surface.

16. The semiconductor transfer device of claim 15, further comprising a horizontal plate on an upper surface of the horizontal extension part and extending in the second direction.

17. The semiconductor transfer device of claim 16, wherein the first-type guide part is movable to extend through the horizontal plate.

18. The semiconductor transfer device of claim 16, further comprising a second-type guide part extending from an upper surface of the horizontal plate at a corner of the horizontal plate,
and wherein the horizontal plate includes the corner at which a first edge extending in the second direction along a circumference of the horizontal plate and a second edge extending in the third direction along the circumference of the horizontal plate intersect.

19. The semiconductor transfer device of claim 15, further comprising:
a second guide cylinder on the third surface of the horizontal extension part and spaced apart from the first guide cylinder in a fourth direction opposite to the second direction, and configured to transmit power; and
a third-type guide part connected to the second guide cylinder and movable in the first direction.

20. The semiconductor transfer device of claim 15, further comprising:
a bracket on the second surface of the vertical extension part and extending in the third direction;
an adsorption part connected to the bracket and configured to adsorb a wafer transfer device;
a pin extending from the adsorption part in the first direction and configured to fix the wafer transfer device; and
a vertical cylinder on the second surface of the vertical extension part and extending in the first direction,
wherein the adsorption part and the pin are movable in the second direction to extend through the vertical extension part in the second direction, and
as a piston included in the vertical cylinder moves in the first direction, movement of the bracket in the second direction is adjusted.
